(19) United States
(12) Patent Application Publication
(10) Pub. No.: US 2026/0090067 A1
(43) Pub. Date: Mar. 26, 2026

(54) SEMICONDUCTOR DEVICE

(71) Applicant: HON HAI PRECISION INDUSTRY CO., LTD., New Taipei City (TW)

(72) Inventors: Jhe-Hao CHANG, Hsinchu City (TW); Jheng-Sheng YOU, Hsinchu City (TW)

(21) Appl. No.: 18/957,915

(22) Filed: Nov. 25, 2024

(30) Foreign Application Priority Data
Sep. 24, 2024 (TW) 113136237

(51) Int. Cl. H01L 27/06; H01L 29/20; H01L 29/778; H01L 29/872

(52) U.S. Cl. CPC H10D 84/01; H10D 8/60; H10D 30/475; H10D 62/8503; H10D 84/811

(57) ABSTRACT

A semiconductor device includes a substrate structure, a source structure, a drain structure, and a gate structure. The substrate structure includes a semiconductor layer. The source structure, the drain structure, and the gate structure are over the semiconductor layer of the substrate structure and are arranged along a first direction. The drain structure includes a plurality of first electrode units and a plurality of second electrode units arranged alternately along a second direction. The second direction is substantially perpendicular to the first direction. Each of the first electrode units includes a p-type semiconductor layer and a first metal electrode over the p-type semiconductor layer. The p-type semiconductor layer has a first base area. Each of the second electrode units includes a second metal electrode. The second metal electrode has a second base area that is greater than the first base area.

### CROSS-REFERENCE TO RELATED APPLICATION

This application claims priority to Taiwan Application Serial Number 113136237, filed September 24, 2024, which is herein incorporated by reference in its entirety.

### BACKGROUND

### Technical Field

The present disclosure relates to a semiconductor device.

### Description of Related Art

III-V compound semiconductors are widely used in integrated circuit components, such as high power field-effect transistors (FET), high frequency transistors, high electron mobility transistors (HEMT), or the like, due to their semiconductor properties. Among high electron mobility transistors, gallium nitride-based materials have received special attention in recent years due to their wide band gap, high saturation rate, and suitability for high frequency and high power density operations. However, in order to cope with the increase in integration density, it is necessary to further reduce the energy consumption and on-state resistance of high electron mobility transistors.

### SUMMARY

According to an embodiment of the disclosure, a semiconductor device includes a substrate structure, a source structure, a drain structure, and a gate structure. The substrate structure includes a semiconductor layer. The source structure, the drain structure, and the gate structure are over the semiconductor layer of the substrate structure and are arranged along a first direction. The drain structure includes a plurality of first electrode units and a plurality of second electrode units. Each of the first electrode units includes a p-type semiconductor layer and a first metal electrode over the p-type semiconductor layer. The p-type semiconductor layer has a first base area. Each of the second electrode units includes a second metal electrode. The second metal electrode has a second base area that is greater than the first base area. The first electrode units and the second electrode units are arranged alternately along a second direction. The second direction is substantially perpendicular to the first direction.

### BRIEF DESCRIPTION OF THE DRAWINGS

FIG. 1 is a top view of a semiconductor device according to some embodiments of the present disclosure;

FIG. 2, FIG. 3, and FIG. 4 are partial cross-sectional views of a semiconductor device according to some embodiments of the present disclosure;

FIG. 5 is a schematic diagram of an equivalent circuit model of a semiconductor device according to some embodiments of the present disclosure;

FIG. 6 is a top view of a semiconductor device according to some other embodiments of the present disclosure; and

FIG. 7 is a top view of a semiconductor device according to yet some other embodiments of the present disclosure.

### DETAILED DESCRIPTION

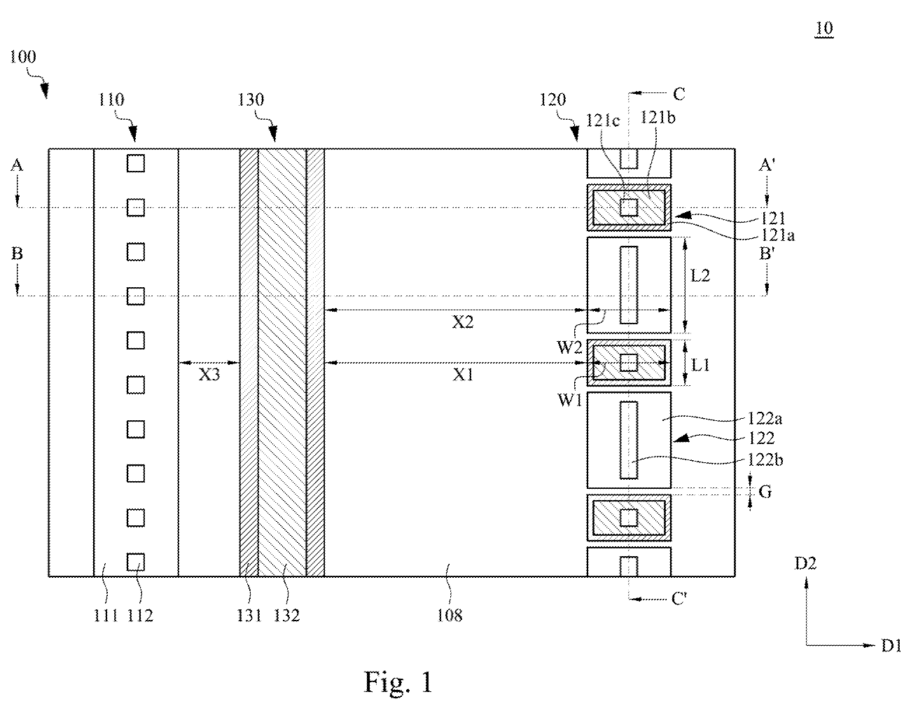

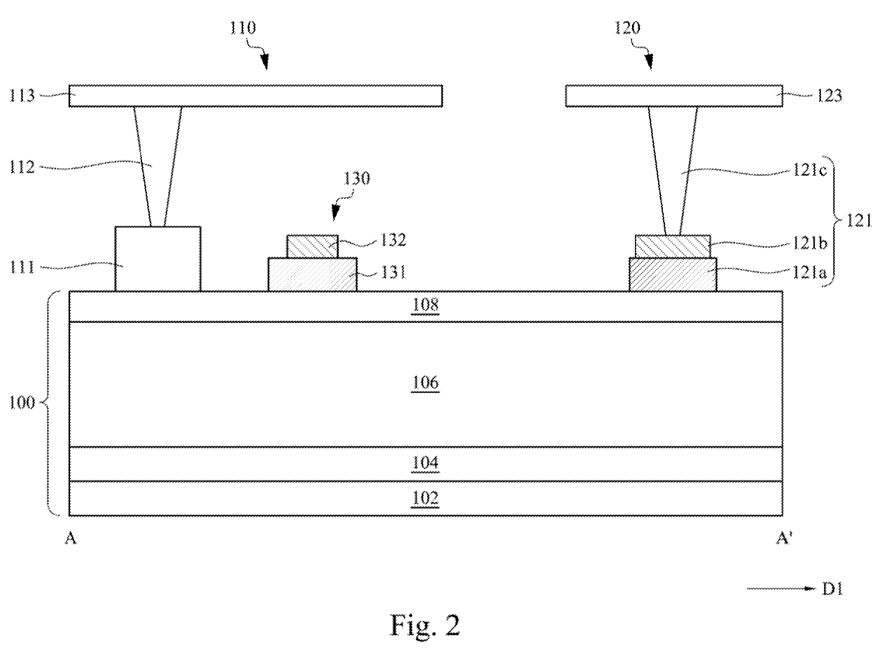

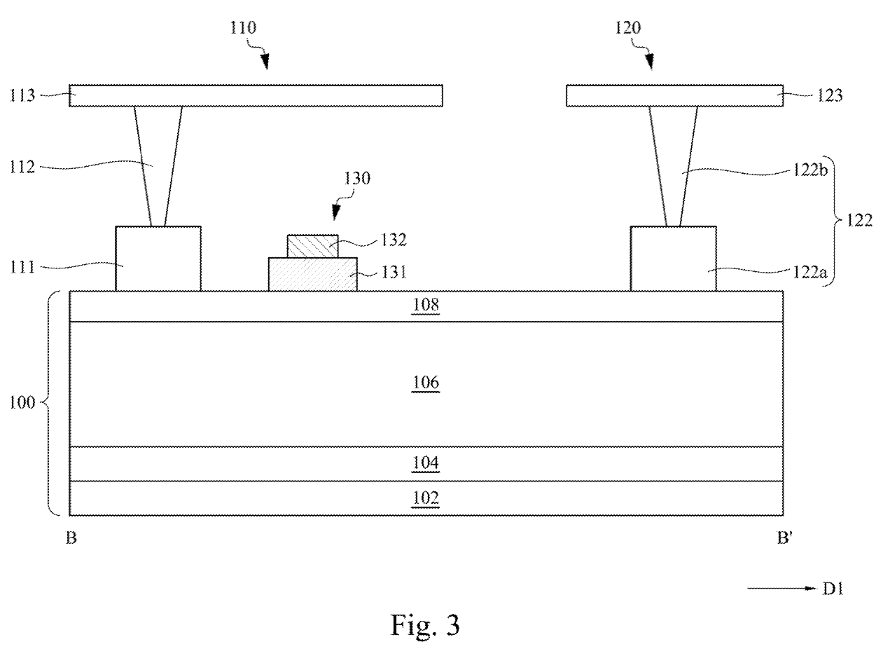

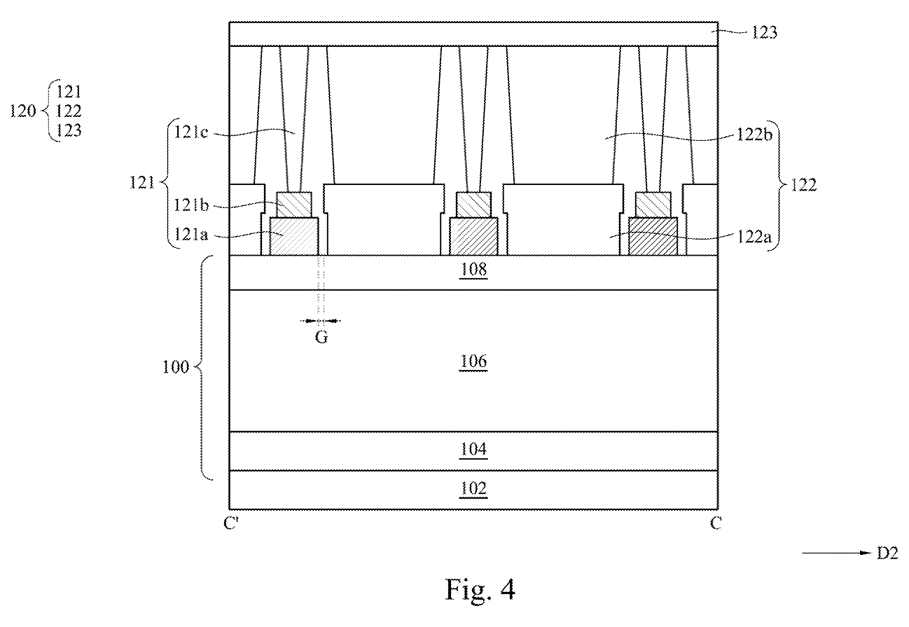

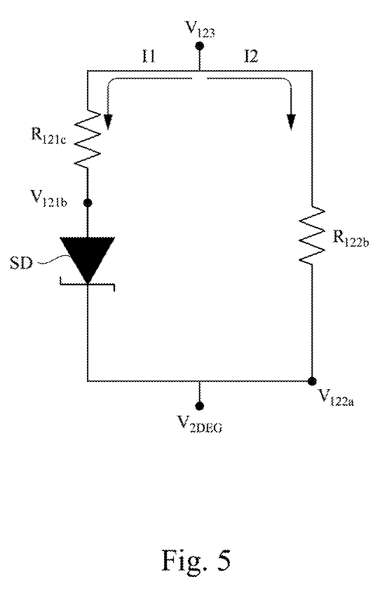

Reference is made to FIG. 1 to FIG. 5. FIG. 1 is a top view of a semiconductor device 10 according to some embodiments of the present disclosure. FIG. 2, FIG. 3, and FIG. 4 are partial cross-sectional views of the semiconductor device 10 along a line A-A’, a line B-B’, and a line C-C’ in FIG. 1, respectively. FIG. 5 is a schematic diagram of an equivalent circuit model of the semiconductor device 10.

As shown in FIG. 1, the semiconductor device 10 includes a substrate structure 100, a source structure 110, a drain structure 120, and a gate structure 130. In greater detail, the source structure 110, the drain structure 120, and the gate structure 130 are over a semiconductor layer 108 of the substrate structure 100 and arranged along a first direction D1. The gate structure 130 is between the source structure 110 and the drain structure 120. The source structure 110 and the gate structure 130 extend along a second direction D2. As shown in FIG. 1, the first direction D1 is substantially perpendicular to a direction of the gate width, and the second direction D2 is substantially parallel to the direction of the gate width.

In some embodiments, the substrate structure 100 includes a semiconductor stack structure. For example, as shown in FIG. 2, FIG. 3, and FIG. 4, the substrate structure 100 includes a substrate 102, a buffer layer 104, a semiconductor layer 106, and a semiconductor layer 108. The buffer layer 104 is over the substrate 102. The semiconductor layer 106 is over the buffer layer 104. The semiconductor layer 108 is over the semiconductor layer 106. In some embodiments, the semiconductor layer 106 and the semiconductor layer 108 include III-V compound semiconductors. For example, the semiconductor layer 106 may include gallium nitride (GaN). The semiconductor layer 108 may include aluminum gallium nitride (AlGaN). As such, the semiconductor layer 106 and the semiconductor layer 108 form a heterojunction interface, which is characterized in a high density two-dimensional electron gas (2DEG) layer. Therefore, the semiconductor device 10 has lower energy consumption and higher power density than silicon-based semiconductor devices.

In some embodiments, the source structure 110 includes a source electrode 111, a plurality of source vias 112, and a source metal 113. As shown in FIG. 1, the source electrode 111 is a strip-shaped material extending along the second direction D2. The source vias 112 are over the source electrode 111 and arranged along the second direction D2. As shown in FIG. 2 and FIG. 3, the source metal 113 is over the source electrode 111 and electrically connected to the source electrode 111 through the source vias 112. In some embodiments, the materials of the source electrode 111 and the source metal 113 may include, but are not limited to, titanium, titanium nitride, aluminum, copper, or combinations thereof.

In some embodiments, the drain structure 120 includes a plurality of first electrode units 121, a plurality of second electrode units 122, and a drain metal 123. As shown in FIG. 1 and FIG. 4, the first electrode units 121 and the second electrode units 122 are arranged alternately and spaced apart along the second direction D2. There is a gap G between one of the first electrode units 121 and one of the second electrode units 122 that is adjacent to the one of the first electrode units 121. Meanwhile, two adjacent ones of the first electrode units 121 are separated from each other and two adjacent ones of the second electrode units 122 are separated from each other, forming island-shaped structures. A central axis of each of the first electrode units 121 coincides with a central axis of each of the second electrode units 122 and is parallel to the second direction D2. For example, the central axis of each of the first electrode units 121 and the central axis of each of the second electrode units 122 coincide with the line C-C’. Detailed features of the first electrode units 121 and the second electrode units 122 will be described in subsequent paragraphs.

In some embodiments, the gate structure 130 includes a gate semiconductor layer 131 and a gate metal electrode 132. As shown in FIG. 1, the gate semiconductor layer 131 and the gate metal electrode 132 are strip-shaped materials extending along the second direction D2. As shown in FIG. 2 and FIG. 3, the gate metal electrode 132 is over the gate semiconductor layer 131. In some embodiments, the gate semiconductor layer 131 includes, but is not limited to, gallium nitride or p-type doped gallium nitride. The gate metal electrode 132 includes, but is not limited to, titanium, titanium nitride, aluminum, copper, or combinations thereof.

As shown in FIG. 2 and FIG. 4, each of the first electrode units 121 includes a p-type semiconductor layer 121a, a first metal electrode 121b over the p-type semiconductor layer 121a, and a first drain via 121c over the first metal electrode 121b. In some embodiments, the p-type semiconductor layer 121a is made of gallium nitride with p-type dopants. In some embodiments, the first metal electrode 121b includes, but is not limited to, titanium, titanium nitride, aluminum, copper, or combinations thereof. The first metal electrode 121b is in contact with a top surface of the p-type semiconductor layer 121a to form a Schottky barrier diode (SBD). A bottom surface of the p-type semiconductor layer 121a is in contact with the semiconductor layer 108. The first metal electrode 121b and the p-type semiconductor layer 121a are electrically connected to the drain metal 123 through the first drain via 121c.

As shown in FIG. 3 and FIG. 4, each of the second electrode units 122 includes a second metal electrode 122a and a second drain via 122b over the second metal electrode 122a. The second metal electrode 122a is in contact with the semiconductor layer 108 to form an ohmic contact. In some embodiments, the second metal electrode 122a includes, but is not limited to, titanium, titanium nitride, aluminum, copper, or combinations thereof. The second metal electrode 122a is electrically connected to the drain metal 123 through the second drain via 122b. As shown in FIG. 4, in the cross-sectional view taken along the line C-C’, the second metal electrode 122a has a lower portion and an upper portion connected to the lower portion. The lower portion of the second metal electrode 122a is in direct contact with the semiconductor layer 108. The upper portion of the second metal electrode 122a is over the lower portion and in contact with the second drain via 122b. The gap G is between an edge of the upper portion of the second metal electrode 122a and an edge of the p-type semiconductor layer 121a. In other words, an orthographic projection area of the second metal electrode 122a of each of the second electrode units 122 projected onto the substrate structure 100 and an orthographic projection area of the p-type semiconductor layer 121a of each of the first electrode units 121 projected onto the substrate structure 100 are separated from each other and do not overlap.

As shown in FIG. 4, a base area of the lower portion of each of the second electrode units 122 may be enlarged to reduce the contact resistance. In other words, a contact area between each of the second electrode units 122 and the semiconductor layer 108 may be increased. In this case, the base area of each of the second electrode units 122 (i.e., the contact area between each of the second electrode units 122 and the semiconductor layer 108) is greater than a base area of each of the first electrode units 121 (i.e., a contact area between each of the first electrode units 121 and the semiconductor layer 108).

Reference is made back to FIG. 1. In some embodiments, a width W1 of the p-type semiconductor layer 121a of each of the first electrode units 121 along the first direction D1 is substantially equal to a width W2 of the second metal electrode 122a of each of the second electrode units 122 along the first direction D1. For example, the width W1 is between about 0.1 μm and about 3 μm. The width W2 is between about 0.1 μm and about 3 μm. In some embodiments, a length L1 of the p-type semiconductor layer 121a of each of the first electrode units 121 along the second direction D2 is less than a length L2 of the second metal electrode 122a of each of the second electrode units 122 along the second direction D2. For example, the length L1 is between about 0.1 μm and about 3 μm. The length L2 is between about 0.1 μm and about 30 μm. As such, the base area and/or a plan view area of each of the second electrode units 122 is increased, thereby reducing its on-state resistance. In this case, in the top view, the area of each of the second electrode units 122 is greater than an area of each of the first electrode units 121.

On the other hand, as shown in FIG. 1, the first drain vias 121c of the first electrode units 121 and the second drain vias 122b of the second electrode units 122 are arranged spaced apart along the second direction D2. In some embodiments, a base area of the second drain via 122b of each of the second electrode units 122 (i.e., a contact area between the second drain via 122b and the second metal electrode 122a of each of the second electrode units 122) is greater than a base area of the first drain via 121c of each of the first electrode units 121 (i.e., a contact area between the first drain via 121c and the first metal electrode 121b of each of the first electrode units 121). As a result, a resistance value of the second drain via 122b of each of the second electrode units 122 is less than a resistance value of the first drain via 121c of each of the first electrode units 121.

Under such configuration, the first electrode units 121 and the second electrode units 122 are spaced apart and electrically connected to the drain metal 123 through the first drain vias 121c and the second drain vias 122b, respectively. As a result, in a conducting state, the first metal electrode 121b of each of the first electrode units 121 and the second metal electrode 122a of each of the second electrode units 122 may have different potentials. To be more specific, referring to FIG. 5, current may flow from the drain metal 123, which has a potential value V₁₂₃, to the two-dimensional electron gas layer, which has a potential value V_{2DEG}, via two paths. The path shown on the left of FIG. 5 passes through the first drain via 121c and the Schottky barrier diode SD formed by the first metal electrode 121b and the p-type semiconductor layer 121a. The path on the right of FIG. 5 passes through the second drain via 122b and the second metal electrode 122a. Therefore, a potential value V_{121b} of the first metal electrode 121b and a potential value V₁₂₂ₐ of the second metal electrode 122a may be different.

As aforementioned, the base area of the second drain via 122b of each of the second electrode units 122 is greater than the base area of the first drain via 121c of each of the first electrode units 121. Therefore, a resistance value R_{122b} of the second drain via 122b of each of the second electrode units 122 is less than a resistance value R_{121c} of the first drain via 121c of each of the first electrode units 121. As such, a current value I1 of current flowing through the path on the left is less than a current value I2 of current flowing through the path on the right. Hence, the energy consumption of each of the first electrode units 121 may be reduced. In addition, the first drain via 121c serves as a protection resistor that may suppress voltage overshoot caused by abnormal disturbance of the drain metal 123 and avoid damage to the Schottky barrier diode SD.

Similarly, as shown in FIG. 4, in some embodiments, a cross-sectional area of the first drain via 121c is less than a cross-sectional area of the second drain via 122b. In some embodiments, a bottom end of the first drain via 121c is lower than a bottom end of the second drain via 122b, and a top surface of the first metal electrode 121b is lower than a top surface of the second metal electrode 122a. In other words, a height of the first drain via 121c may be greater than a height of the second drain via 122b. Thus, the resistance value R_{122b} may be much less than the resistance value R_{121c}. Moreover, a thickness of the p-type semiconductor layer 121a is less than a thickness of the second metal electrode 122a.

Furthermore, as shown in FIG. 1, in some embodiments, an edge of the p-type semiconductor layer 121a of each of the first electrode units 121 is flush with an edge of the second metal electrode 122a of each of the second electrode units 122. In this way, the gate-drain length (L_{gd}, which is equivalent to a distance X1 and a distance X2 shown in FIG. 1) may be maximized, thereby reducing electric field spikes, providing a greater breakdown voltage, and improving device reliability. In this case, the distance X1 between the p-type semiconductor layer 121a of each of the first electrode units 121 and the gate semiconductor layer 131 along the first direction D1 is substantially equal to the distance X2 between the second metal electrode 122a of each of the second electrode units 122 and the gate semiconductor layer 131 along the first direction D1. It should be noted that both the distance X1 and the distance X2 are greater than a distance X3 between the source structure 110 and the gate structure 130.

Next, a method for forming the semiconductor device 10 according to some embodiments of the present disclosure will be described accompanied with FIG. 1 and FIG. 4. First, the substrate structure 100 is provided. For example, the buffer layer 104, the semiconductor layer 106, and the semiconductor layer 108 are sequentially formed on the substrate 102. Next, the p-type semiconductor layers 121a are formed separated from each other and arranged along the second direction D2. In some embodiments, the gate semiconductor layer 131 may be formed simultaneously in this step. Next, the first metal electrodes 121b are formed over the p-type semiconductor layers 121a. In some embodiments, the gate metal electrode 132 may be formed simultaneously in this step. Next, the second metal electrodes 122a are formed between every two adjacent ones of the p-type semiconductor layers 121a, so that the p-type semiconductor layers 121a and the second metal electrodes 122a are arranged alternately and spaced apart along the second direction D2. In some embodiments, the source electrode 111 may be formed simultaneously in this step. Next, the first drain vias 121c and the second drain vias 122b are formed over the first metal electrodes 121b and the second metal electrodes 122a, respectively, such that the base areas of the second drain vias 122b of the second electrode units 122 are greater than the base areas of the first drain vias 121c of the first electrode units 121. In some embodiments, the source vias 112 may be formed simultaneously over the source electrode 111 in this step. Next, the drain metal 123 is formed over the first drain vias 121c and the second drain vias 122b. In some embodiments, the source metal 113 may be formed over the source vias 112 at the same time.

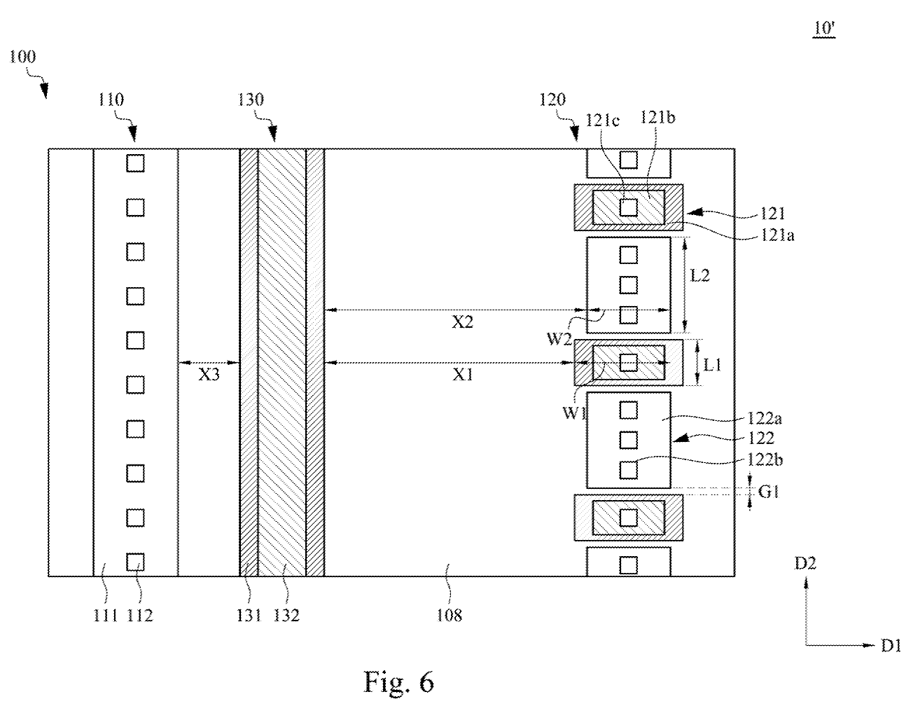

Reference is made to FIG. 6. FIG. 6 is a top view of a semiconductor device 10′ according to some other embodiments of the present disclosure. One of the differences between the semiconductor device 10’ and the semiconductor device 10 is that a width W1 of the p-type semiconductor layer 121a of each of the first electrode units 121 of the semiconductor device 10’ along the first direction D1 is different from a width W2 of the second metal electrode 122a of each of the second electrode units 122 of the semiconductor device 10’ along the first direction D1. For example, the width W1 is greater than the width W2. In some embodiments, a length L1 of the p-type semiconductor layer 121a of each of the first electrode units 121 of the semiconductor device 10’ along the second direction D2 is less than a length L2 of the second metal electrode 122a of each of the second electrode units 122 of the semiconductor device 10’ along the second direction D2. As a result, in the top view, a plan view area of each of the first electrode units 121 is less than a plan view area of each of the second electrode units 122 to increase the area ratio for which each of the second electrode units 122 accounts to an extent that the on-resistance is reduced.

In addition, another difference between the semiconductor device 10′ and the semiconductor device 10 is that there may be three second drain vias 122b arranged separately along the second direction D2 over the second metal electrode 122a of each of the second electrode units 122 of the semiconductor device 10′. Each of the second drain vias 122b has dimensions similar to dimensions of the first drain vias 121c. In such embodiments, a sum of the base areas of the second drain vias 122b of the second electrode units 122 is greater than a sum of the base areas of the first drain vias 121c of the first electrode units 121 so that the total resistance value of the second drain vias 122b of the second electrode units 122 is less than the total resistance value of the first drain vias 121c of the first electrode units 121. In some other embodiments, there may be more than one first drain via 121c over the first metal electrode 121b of each of the first electrode units 121.

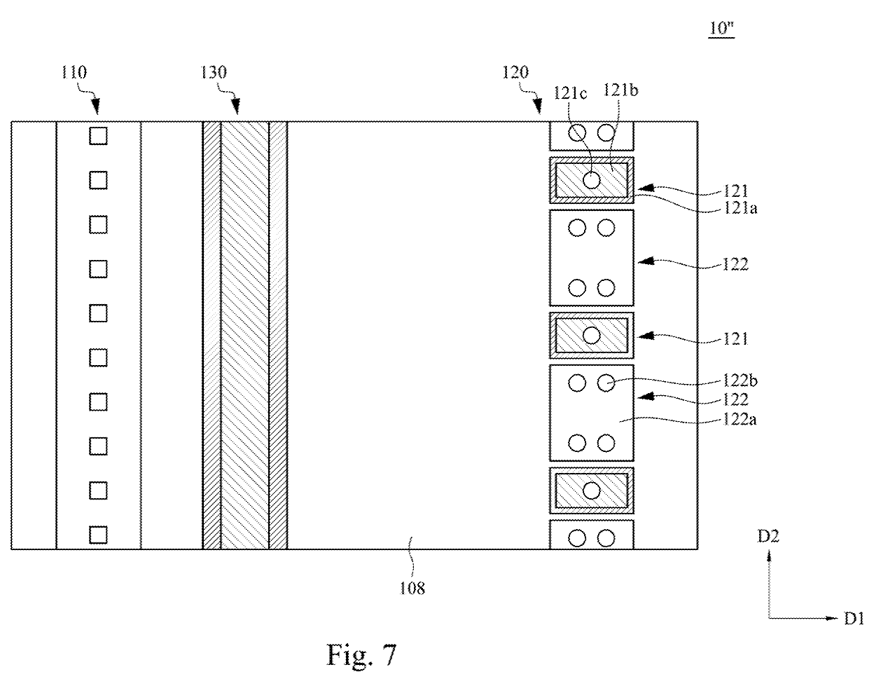

In some embodiments, the first drain vias 121c and the second drain vias 122b may have any shape. For example, reference is made to FIG. 7, which is a top view of a semiconductor device 10″ according to yet some other embodiments of the present disclosure. One difference between the semiconductor device 10″ and the semiconductor device 10 is that the first drain vias 121c and the second drain vias 122b of the semiconductor device 10″ have a circular profile in the top view. Also, in such embodiments, there are four second drain vias 122b distributed over the second metal electrode 122a of each of the second electrode units 122. Similarly, the sum of the base areas of the second drain vias 122b of the second electrode units 122 is greater than the sum of the base areas of the first drain vias 121c of the first electrode units 121 such that the total resistance value of the second drain vias 122b of the second electrode units 122 is less than the total resistance value of the first drain vias 121c of the first electrode units 121.

According to the foregoing recitations of the embodiments of the disclosure, it may be seen that in some embodiments of the semiconductor device of the present disclosure, the first electrode units and the second electrode units of the drain structure are arranged alternately and spaced apart. Each of the first electrode units includes the first metal electrode and the p-type semiconductor layer that form a Schottky barrier diode. Each of the second electrode units includes the second metal electrode that forms an ohmic contact with the underlying semiconductor layer. At the same time, the base area of the second metal electrode of each of the second electrode units is set to be greater than the base area of the p-type semiconductor layer of each of the first electrode units. In this way, in the conducting state, the first metal electrode of each of the first electrode units and the second metal electrode of each of the second electrode units have different potentials. In turn, energy consumption may be further reduced by modifying the relationship of the contact areas of the first electrode units, the second electrode units, and the semiconductor layer of the substrate structure, and damage caused by voltage overshoot may be suppressed.

What is claimed is:

1. A semiconductor device, comprising:
a substrate structure comprising a semiconductor layer;
a source structure over the semiconductor layer of the substrate structure;
a gate structure over the semiconductor layer; and
a drain structure over the semiconductor layer and arranged along a first direction with the source structure and the gate structure, wherein the drain structure comprises:
a plurality of first electrode units, wherein each of the first electrode units comprises a p-type semiconductor layer and a first metal electrode over the p-type semiconductor layer, wherein the p-type semiconductor layer has a first base area; and
a plurality of second electrode units, wherein each of the second electrode units comprises a second metal electrode, wherein the second metal electrode has a second base area that is greater than the first base area,
wherein the first electrode units and the second electrode units are arranged alternately along a second direction, and the second direction is substantially perpendicular to the first direction.

2. The semiconductor device of claim 1, wherein the p-type semiconductor layer of each of the first electrode units and the second metal electrode of each of the second electrode units are separated from each other.

3. The semiconductor device of claim 1, wherein in a top view, an area of each of the first electrode units is less than an area of each of the second electrode units.

4. The semiconductor device of claim 1, wherein a width of the p-type semiconductor layer along the first direction is substantially equal to a width of the second metal electrode along the first direction.

5. The semiconductor device of claim 1, wherein a width of the p-type semiconductor layer along the first direction is different from a width of the second metal electrode along the first direction.

6. The semiconductor device of claim 1, wherein a length of the p-type semiconductor layer along the second direction is less than a length of the second metal electrode along the second direction.

7. The semiconductor device of claim 1, wherein a thickness of the p-type semiconductor layer is less than a thickness of the second metal electrode.

8. The semiconductor device of claim 1, wherein the drain structure further comprises a drain metal, each of the first electrode units further comprises at least one first drain via over the first metal electrode and electrically connected to the drain metal, and each of the second electrode units further comprises at least one second drain via over the second metal electrode and electrically connected to the drain metal.

9. The semiconductor device of claim 8, wherein a bottom end of the at least one first drain via is lower than a bottom end of the at least one second drain via.

10. The semiconductor device of claim 8, wherein the at least one first drain via and the at least one second drain via are arranged spaced apart along the second direction.
